(19) United States
(12) Patent Application Publication
(10) Pub. No.: US 2012/0149202 A1
(43) Pub. Date: Jun. 14, 2012

(54) METHOD FOR FABRICATING SEMICONDUCTOR DEVICE

(76) Inventor: Seung-Seok PYO, Gyeonggi-do (KR)

(21) Appl. No.: 12/980,507

(22) Filed: Dec. 29, 2010

(30) Foreign Application Priority Data
Dec. 9, 2010 (KR) 10-2010-0125526

(51) Int. Cl. H01L 21/475

(52) U.S. Cl. 438/696; 257/E21.488

(57) ABSTRACT

A method for fabricating a semiconductor device includes forming a trench by etching a substrate using a hard mask layer as an etch barrier, forming an insulation material which covers sidewalls of the trench, forming a sacrificial material which fills the trench and is planarized to expose the surface of the hard mask layer, forming a masking layer having a damaged region over the sacrificial material, selectively removing the damaged region of the masking layer, exposing a portion of the insulation material, which is formed at a sidewall of the trench, by etching a portion of the sacrificial material using the remaining masking layer as a barrier, and forming a side contact by removing the exposed insulation material.

### CROSS-REFERENCE TO RELATED APPLICATIONS

The present application claims priority of Korean Patent Application No. 10-2010-0125526, filed on Dec. 9, 2010, which is incorporated herein by reference in its entirety.

### BACKGROUND OF THE INVENTION

Exemplary embodiments of the present invention relate to a method for fabricating a semiconductor device, and more particularly, to a method for forming a side contact of a semiconductor device.

A vertical transistor type cell has a three-dimensional structure which includes a body, an active region formed on the body in a pillar shape, a buried bitline (BBL), and a vertical gate (VG).

Adjacent active regions are isolated by a trench, and the buried bitline is formed within the trench. The buried bitline is electrically connected to a sidewall of the body.

The vertical gate formed on the buried bitline is formed at a sidewall of the pillar, and a source and a drain are formed within the pillar. A vertical channel is formed between the source and the drain by the vertical gate.

A one-side-contact (OSC) process is used to drive a single cell through a single buried bitline. The OSC process is also called a single-side-contact (SSC) process. Hereinafter, the term “OSC process” will be used. The OSC process refers to a process which insulates one of adjacent active regions and forms a bitline contact (BLC) in another active region.

The OSC process selectively exposes a sidewall of the active region. In memory devices that are high-integrated, the OSC process is complicated because an aspect ratio of an active region is relatively large.

In an OSC process, a liner polysilicon deposition and a tilt ion implantation may be used.

After gap-filling a sacrificial layer between trenches, the sacrificial layer is recessed by a desired depth. Then, a liner polysilicon layer is deposited over a resulting structure, and a tilt ion implantation is performed thereon. Accordingly, the liner polysilicon layer is divided into an ion implanted region and a non-implanted region by using a height difference in the recessed sacrificial layer.

The non-implanted region is selectively removed, and an OSC process is performed using the ion implanted region as a mask.

However, due to the height difference in the recessed sacrificial layer, the tilt ion implantation process may not performed uniformly. Consequently, a sidewall of the active region may not be exposed at a desired position or to a desired depth.

### SUMMARY OF THE INVENTION

An embodiment of the present invention is directed to a method for fabricating a semiconductor device, which can form a side contact with a uniform position and height.

In accordance with an embodiment of the present invention, a method for fabricating a semiconductor device includes forming a trench by etching a substrate using a hard mask layer as an etch barrier, forming an insulation material which covers sidewalls of the trench, forming a sacrificial material which fills the trench and is planarized to expose the surface of the hard mask layer, forming a masking layer having a damaged region over the sacrificial material, selectively removing the damaged region of the masking layer, exposing a portion of the insulation material, which is formed at a sidewall of the trench, by etching a portion of the sacrificial material using the remaining masking layer as a barrier, and forming a side contact by removing the exposed insulation material.

In accordance with another embodiment of the present invention, a method for fabricating a semiconductor device includes forming a trench by etching a substrate using a hard mask layer as an etch barrier, forming an insulation material which covers sidewalls of the trench, forming a sacrificial material which fills the trench and is planarized to expose the surface of the hard mask layer, sequentially forming a passivation layer and a masking layer over the sacrificial material, forming a first damaged region in the masking layer, selectively removing the first damaged region, forming a second damaged region in the passivation layer, selectively removing the passivation layer so that the second damaged region remains, exposing a portion of the insulation material, which is formed at a sidewall of the trench, by etching a portion of the sacrificial material using the second damaged region as a barrier, and forming a side contact by removing the exposed insulation material.

### BRIEF DESCRIPTION OF THE DRAWINGS

FIGS. 1A to 1K illustrate a method for forming a side contact of a semiconductor device in accordance with a first embodiment of the present invention.

FIGS. 2A to 2F illustrate a method for forming a side contact of a semiconductor device in accordance with a second embodiment of the present invention.

FIGS. 3A to 3H illustrate a method for forming a side contact of a semiconductor device in accordance with a third embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

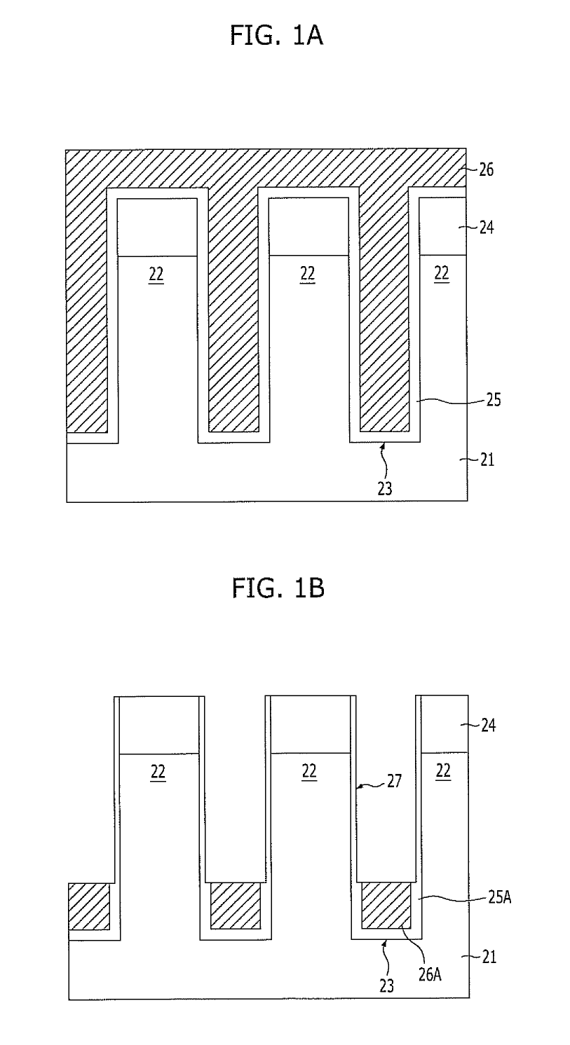

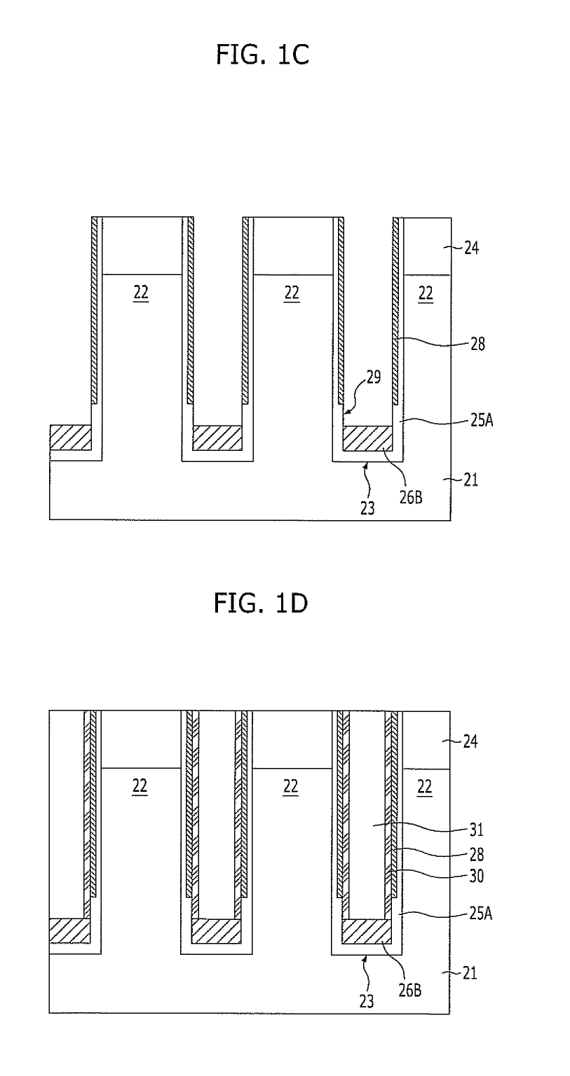

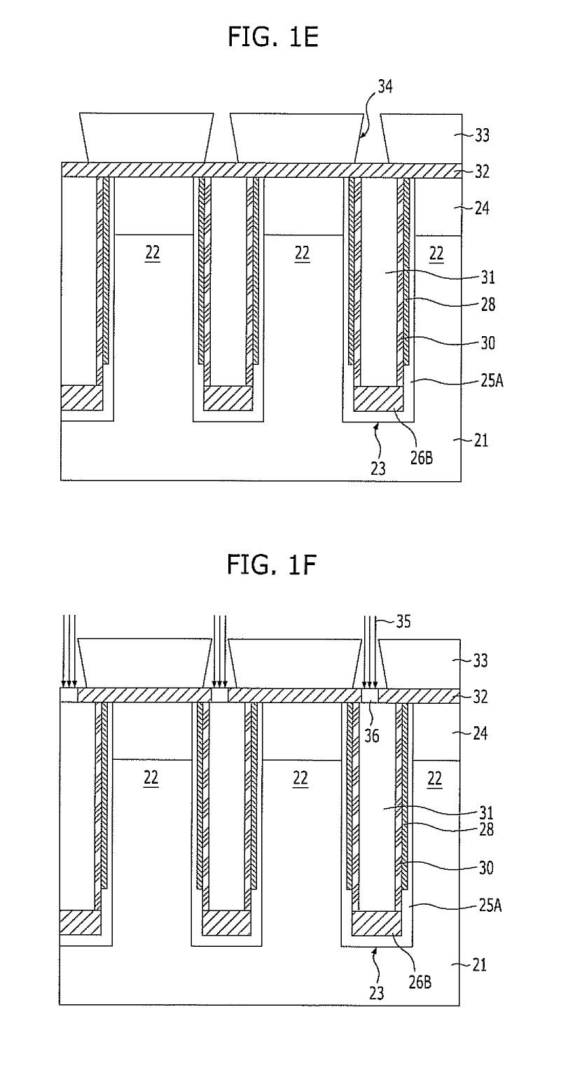

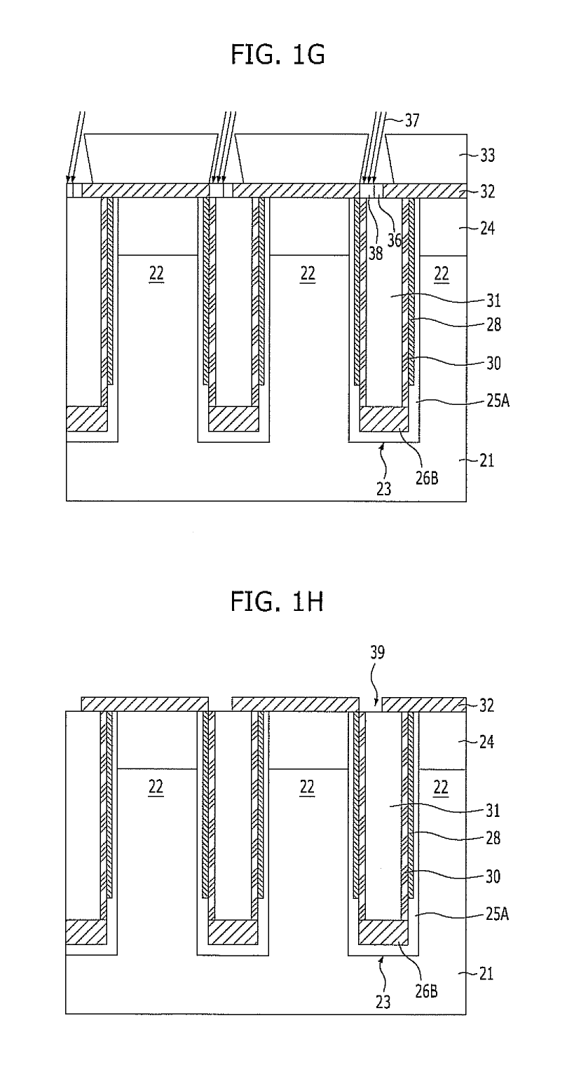

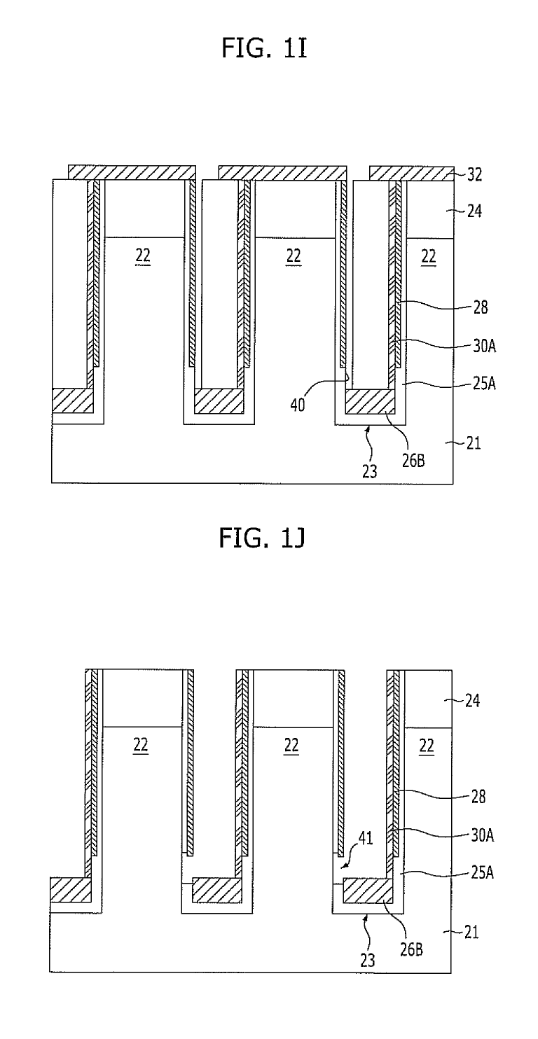

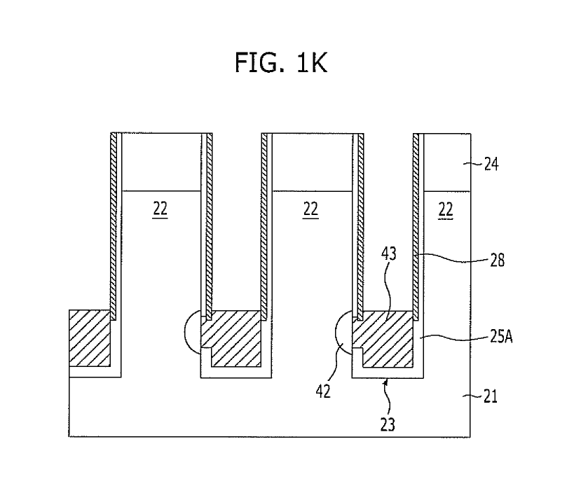

FIGS. 1A to 1K illustrate a method for forming a side contact of a semiconductor device in accordance with a first embodiment of the present invention.

Referring to FIG. 1A, a hard mask layer 24 is formed on a substrate 21. The substrate 21 includes a silicon substrate. The hard mask layer 24 includes a nitride layer. In addition, the hard mask layer 24 may have a multilayer structure including an oxide layer and a nitride layer. For example, the hard mask layer 24 may be formed by sequentially stacking a hard mask (HM) nitride layer and an HM oxide layer. According to another example, the hard mask layer 24 may be formed by sequentially stacking an HM nitride layer, an HM oxide layer, an HM SiON layer, and an HM carbon layer. In a case in which the HM nitride layer is included, a pad oxide layer may be further formed between the substrate 21 and the hard mask layer 24. The hard mask layer 24 is formed using a photoresist pattern (not shown).

A trench etch process is performed using the hard mask layer 24 as an etch barrier. For example, bodies 22 are formed by etching the substrate 21 by a desired depth using the hard mask layer 24 as an etch barrier. The bodies 22 are separated from one another by trenches 23. The body 22 includes an active region in which a transistor is to be formed. The body 22 has two sidewalls. The trench etch process includes an anisotropic etch process. In a case in which the substrate 21 is a silicon substrate, an anisotropic etch process may include a plasma dry etch process which uses Cl₂ gas or HBr gas solely or a mixture of Cl₂ gas and HBr gas. Due to the above-described trenches 23, the plurality of bodies 22 are formed on the substrate 21. The body 22 includes a line type pillar such as a line type active pillar. Here, an active pillar refers to a pillar type active region.

A first liner layer 25 is formed as an insulation layer. The first liner layer 25 includes an oxide layer such as a silicon oxide layer.

A first sacrificial layer 26 gap-filling the trenches 23 between the bodies 22 is formed on the first liner layer 25. The first sacrificial layer 26 may be formed of undoped polysilicon or amorphous silicon.

Referring to FIG. 1B, the first sacrificial layer 26 is planarized until the surface of the hard mask layer 24 is exposed. The planarization of the first sacrificial layer 26 is performed by a chemical mechanical polishing (CMP) process. An etchback process is then performed. A first sacrificial pattern 26A recessed by the etchback process is formed. During the CMP process, the first liner layer 25 on the hard mask layer 24 may be polished. Accordingly, a first liner pattern 25A is formed to cover both sidewalls of the hard mask layer 24 and the trench 23. The first liner pattern 25A also covers the bottom of the trench 23.

The first liner pattern is thinned by a wet etch process, as indicated by reference numeral 27. At this time, the wet etch time is adjusted so that the first liner pattern 25 remains with a desired thickness at the sidewall of the body 22.

Referring to FIG. 1C, a second liner pattern 28 is formed in the thinned region of the first liner pattern 25A. The forming of the second liner pattern 28 includes forming a nitride layer on a resulting structure including the first sacrificial pattern 26A, and performing an etchback process thereon. The second liner pattern 28 has a spacer shape.

The first sacrificial pattern 26A (shown in FIG. 1B) is recessed by a desired depth using the second liner pattern 28 as an etch barrier. Accordingly, the surface of the first liner pattern 25A is partially exposed as indicated by reference numeral 29. The recessed first sacrificial pattern 26A is represented by reference numeral 26B. In a case in which the first sacrificial pattern 26B includes polysilicon, the recess process is performed by an etchback process.

Referring to FIG. 1D, a metal nitride layer is conformally formed on a resulting structure including the first sacrificial pattern 26B. A spacer etch process is performed to form a sacrificial spacer 30. The sacrificial spacer 30 covers the second liner pattern 28 and the first liner pattern 25A at each sidewall of the body 22. The sacrificial spacer 30 includes a titanium nitride (TiN) layer.

A second sacrificial layer 31 is formed to fill a gap between the bodies 22 in which the sacrificial spacer 30 is formed. The second sacrificial layer 31 includes an oxide layer. The second sacrificial layer 31 includes a spin on dielectric (SOD) layer.

The second sacrificial layer 31 is planarized until the surface of the hard mask layer 24 is exposed. The planarization of the second sacrificial layer 31 is performed using a CMP process.

As described above, an insulation material including the first liner pattern 25A and the second liner pattern 28 is formed on the surface of the trench 23. A sacrificial material including the first sacrificial pattern 26B, the second sacrificial layer 31, and the sacrificial spacer 30 gap-fills the trench 23, and the surface of the sacrificial material is planarized to expose the surface of the hard mask layer 24. Referring to FIG. 1E, a masking layer 32 is formed on a resulting structure including the planarized second sacrificial layer 31. The masking layer 32 is formed using a nitride layer. The masking layer 32 includes a silicon nitride (Si₃N₄) layer.

A barrier pattern 33 is formed on the masking layer 32. The sidewall profile of the barrier pattern 33 has a negative slope 34. The barrier pattern 33 may include a photoresist pattern. When the photoresist pattern is formed, an exposure process and a development process are performed. However, in a case in which a negative photoresist layer is used, an exposure region is not removed during the development process. In the exposure process, as the depth of the exposed area becomes deeper, an amount of exposure is reduced. Accordingly, since an amount of exposure is large at the upper portion of the negative photoresist layer, the upper portion of the negative photoresist layer is removed less extensively than the lower portion thereof to trace a negative slope 34.

Referring to FIG. 1F, a primary ion implantation process 35 is performed using the barrier pattern 33 as an ion implantation barrier. At this time, the primary ion implantation process 35 is performed in a vertical direction. Accordingly, a first damaged region 36 is formed in the masking layer 32.

The primary ion implantation process 35 uses BF₂ as a dopant source. Accordingly, the first damaged region 36 is doped with boron. In a case in which the masking layer 32 includes a silicon nitride layer, the first damaged region 36 becomes a silicon boron nitride (SiBN) layer.

Referring to FIG. 1G, a secondary ion implantation process 37 is performed using the barrier pattern 33 as an ion implantation barrier. At this time, the secondary ion implantation process 37 is performed at a tilted angle while adjusting the tilted angle according to the negative slope 34 of the barrier pattern 33. That is, a tilt angle is set according to an angle of the negative slope 34. For example, when the negative slope 34 has an angle of 30 degrees, the secondary ion implantation process 37 is performed at a tilt angle of 30 degrees. Accordingly, a second damaged region 38 is formed in the masking layer 32. During the secondary ion implantation process 37, a damaged region overlapped with the primary ion implantation process 35 may be formed. One end of the second damaged region 38 covers at least the top surface of the sacrificial spacer 30. Therefore, one of the sacrificial spacers 30 in each trench 23 is covered by the second damaged region 38 and the other spacer 30 is covered by the undoped masking layer 32.

The secondary ion implantation process 37 uses BF₂ as a dopant source. Accordingly, the second damaged region 38 is doped with boron. In a case in which the masking layer 32 includes a silicon nitride layer, the second damaged region 38 becomes a silicon boron nitride (SiBN) layer.

As described above, the masking layer 32 is divided into the damaged region and the undamaged region by the primary ion implantation process 35 and the secondary ion implantation process 37. The damaged region includes the first damaged region 36 and the second damaged region 38. One end of the second damaged region 38 covers the top surface of the sacrificial spacer 30, and the other end thereof covers a portion of the surface of the second sacrificial layer 31.

Referring to FIG. 1H, the barrier pattern 33 is removed. In a case in which the barrier pattern 33 is a photoresist pattern, it is stripped using oxygen plasma.

The first damaged region 36 and the second damaged region 38 are selectively removed. The first damaged region 36 and the second damaged region 38 are regions of the mask layer 32 which are doped and damaged by the ion implantation. An etch rate is different depending on the absence and presence of doping. For example, in a case in which the masking layer 32 is a silicon nitride layer, the first damaged region 36 and the second damaged region 38 are silicon boron nitride layers. According to an example, the etch rate is faster in the silicon boron nitride layer than in the silicon nitride layer. Therefore, the silicon boron nitride layer may be selectively removed using a buffered oxide etchant (BOE) chemical, which is a mixture of NH₄F and HF. The undoped masking layer 32 is not removed because it has an etch selectivity to the BOE chemical. Although the BOE chemical is a solution for etching an oxide layer, it is also used to etch the silicon boron nitride layer. During the ion implantation process, the damaged region is formed, and the damaged region is easily etched by the HF or the BOE chemical. Therefore, the silicon boron nitride layer is easily etched by the BOE chemical. In the BOE chemical, the etch rate of the silicon nitride layer into which boron ions are implanted is about 425 times faster than that of the undoped silicon nitride layer. The etch rate is further increased as the number of times of the ion implantation process is performed increases.

As described above, when the first damaged region 36 and the second damaged region 38 are removed, an open region 39 is formed in the masking layer 32. One of the sacrificial spacers 30 in each trench 23 is exposed by the open region 39. In addition, the top surface of the second sacrificial layer 31 is partially exposed by the open region 39.

Referring to FIG. 1I, the sacrificial spacer 30 exposed by the open region 39 is removed. In a case in which the sacrificial spacer 30 includes a titanium nitride layer, a sulfuric peroxide mixture (SPM) cleaning is used. By removing the sacrificial spacer 30, a portion of the first liner pattern 25A is exposed as indicated by reference numeral 40. The remaining sacrificial spacer is represented by reference numeral 30A.

Referring to FIG. 1J, the masking layer 32 is removed. The masking layer 32 is removed using a phosphoric acid solution.

A side contact 41 is formed by selectively removing the exposed first liner pattern 25A. Since the first liner pattern 25A is an oxide layer, a BOE chemical is used. When the BOE chemical is used in order to form the side contact 41, the second sacrificial layer 31 being an oxide layer is also removed at the same time.

The side contact 41 exposes the body 22, that is, a portion of a sidewall of the trench 23. In forming the side contact 41, the first sacrificial pattern 26B, the sacrificial spacer 30A, and the second liner pattern 28 serve as an etch barrier.

Referring to FIG. 1K, the first sacrificial pattern 26B and the sacrificial spacer 30A are removed. Since the first sacrificial pattern 26B is a polysilicon layer, it is removed using a mixed chemical of a nitric acid (HNO₃) and a hydrofluoric acid (HF). Since the sacrificial spacer 30A is a titanium nitride layer, it is removed using an SPM solution.

A junction region 42 is formed at a sidewall of the body 22 exposed by the side contact 41. According to an example, the junction region 42 may be formed using an ion implantation process or a plasma doping process. According to another example, the junction region 42 may be formed by gap-filling a doped layer such as a doped polysilicon layer and performing a thermal treatment thereon. A dopant doped into the doped layer may include an N-type impurity such as phosphorus (P). Therefore, the junction region 42 becomes an N-type junction.

A buried bitline 43 which is connected to the junction region 42 and partially fills the trench 23 is formed. The buried bitline 43 includes a titanium (Ti) layer, a titanium nitride (TiN) layer, and a tungsten (W) layer. For example, the buried bitline 43 is formed by thinly forming a titanium layer and a titanium nitride layer and gap-filling with a tungsten layer. A planarization process and an etchback process are performed so that the trench 23 is partially filled. The titanium layer and the titanium nitride layer are a barrier metal. Optionally, after forming the barrier metal, a silicide may be formed on the surface of the junction region 42. The silicide serves as an ohmic contact between the junction region 42 and the buried bitline 43 and reduces a contact resistance.

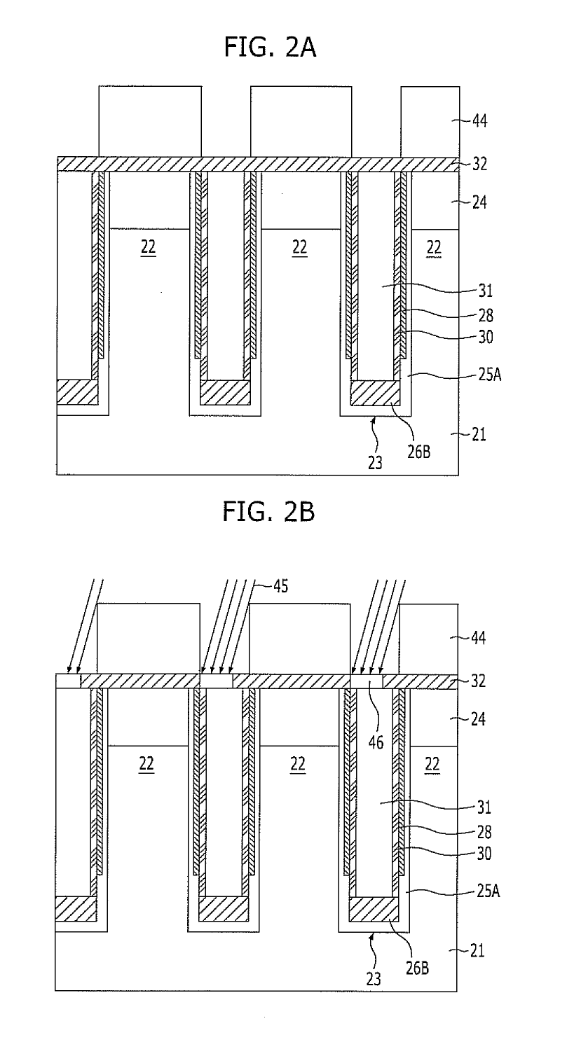

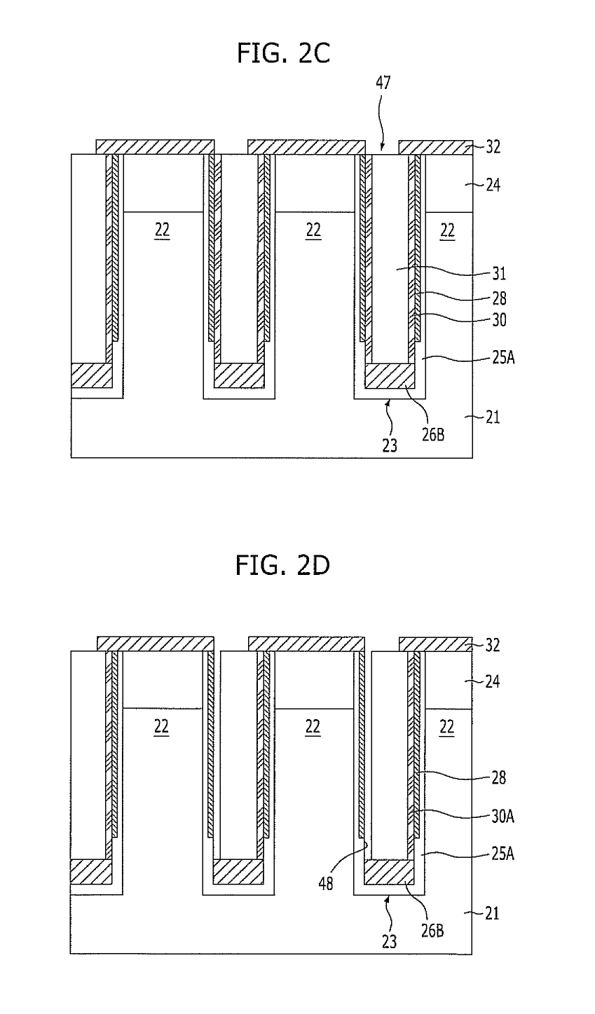

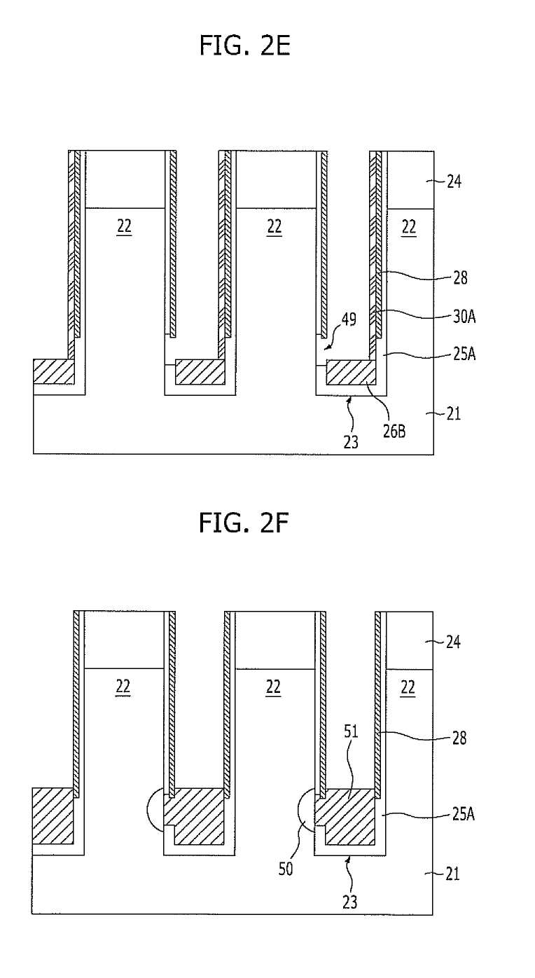

FIGS. 2A to 2F illustrate a method for forming a side contact of a semiconductor device in accordance with a second embodiment of the present invention.

Referring to FIG. 2A, a sacrificial spacer 30 and a planarized second sacrificial layer 31 are formed using the method of FIGS. 1A to 1D.

A masking layer 32 is formed on a resulting structure including the planarized second sacrificial layer 31. The masking layer 32 is formed using a nitride layer. The masking layer 32 includes a silicon nitride layer.

A barrier pattern 44 is formed on the masking layer 32. The barrier pattern 44 has a vertical sidewall profile. The barrier pattern 44 may include a photoresist pattern. The barrier pattern 44 includes a positive photoresist layer.

Referring to FIG. 2B, a tilt ion implantation process 45 is performed using the barrier pattern 44 as an ion implantation barrier. At this time, the tilt ion implantation process 45 is performed at a desired tilt angle. Accordingly, a damaged region 46 is formed in the masking layer 32.

The tilt ion implantation process 45 uses BF₂ as a dopant source. Accordingly, the damaged region 46 is doped with boron. In a case in which the masking layer 32 includes a silicon nitride layer, the damaged region 46 becomes a silicon boron nitride (SiBN) layer. The tilt ion implantation process 45 may be performed several times.

One end of the damaged region 46 covers at least the top surface of the sacrificial spacer 30. Therefore, one of the sacrificial spacers 30 at each trench 23 is covered by the damaged region 46, and the other spacer 30 is covered by the undoped masking layer 32.

Referring to FIG. 2C, the barrier pattern 44 is removed. In a case in which the barrier pattern 44 is a photoresist pattern, it is stripped using oxygen plasma.

The damaged region 46 is selectively removed. The damaged region 46 is a region of the mask layer 32 which is damaged by the ion implantation. An etch rate is different depending on the absence and presence of doping. For example, in a case in which the masking layer 32 is a silicon nitride layer, the damaged region 46 is a silicon boron nitride layer. According to an example, the etch rate is faster in the silicon boron nitride layer than in the silicon nitride layer. Therefore, the silicon boron nitride layer may be selectively removed using a BOE chemical. The undoped masking layer 32 is not removed because it has an etch selectivity to the BOE chemical. Although the BOE chemical is a solution for etching an oxide layer, it is also used to etch the silicon boron nitride layer. During the ion implantation process, the damaged region is formed, and the damaged region is easily etched by the HF or the BOE chemical. Therefore, the silicon boron nitride layer is easily etched by the BOE chemical. In the BOE chemical, the etch rate of the silicon nitride layer on which the tilt ion implantation process 45 of boron has been performed is about 425 times faster than that of the undoped silicon nitride layer. The etch rate is further increased as the number of times of the ion implantation process is performed increases. According to an example, when the tilt ion implantation process 45 is performed twice, the etch rate of the silicon nitride layer on which the tilt ion implantation process has been performed is about 631 times faster, as compared to that of the undoped silicon nitride layer.

As described above, when the damaged region 46 is removed, an open region 47 is formed in the masking layer 32. One of the sacrificial spacers 30 at each trench 23 is exposed by the open region 47. In addition, the top surface of the second sacrificial layer 31 is partially exposed by the open region 47.

Referring to FIG. 2D, the sacrificial spacer 30 exposed by the open region 47 is removed. In a case in which the sacrificial spacer 30 includes a titanium nitride layer, an SPM cleaning is used. By removing the sacrificial spacer 30, a portion of the first liner pattern 25A is exposed as indicated by reference numeral 48. The remaining sacrificial spacer is represented by reference numeral 30A.

Referring to FIG. 2E, the masking layer 32 is removed. The masking layer 32 is removed using a phosphoric acid solution.

A side contact 49 is formed by selectively removing the exposed first liner pattern 25A. Since the first liner pattern 25A is an oxide layer, a BOB chemical is used. When the BOE chemical is used in order to form the side contact 49, the second sacrificial layer 31 being an oxide layer is also removed at the same time.

The side contact 49 exposes a portion of a sidewall of the body 22. In forming the side contact 49, the first sacrificial pattern 26B, the sacrificial spacer 30A, and the second liner pattern 28 serve as an etch barrier.

Referring to FIG. 2F, the first sacrificial pattern 26B and the sacrificial spacer 30A are removed. Since the first sacrificial pattern 26B is a polysilicon layer, it is removed using a mixed chemical of a nitric acid and a hydrofluoric acid. The sacrificial spacer 30A is removed using an SPM solution.

A junction region 50 is formed at a sidewall of the body 22 exposed by the side contact 49. According to an example, the junction region 50 may be formed using an ion implantation process or a plasma doping process. According to another example, the junction region 50 may be formed by gap-filling a doped layer such as a doped polysilicon layer and performing a thermal treatment thereon. A dopant doped into the doped layer may include an N-type impurity such as phosphorus (P). Therefore, the junction region 50 becomes an N-type junction.

A buried bitline 51 which is connected to the junction region 50 and partially fills the trench 23 is formed. The buried bitline 51 includes a titanium (Ti) layer, a titanium nitride (TiN) layer, and a tungsten (W) layer. For example, the buried bitline 51 is formed by thinly forming a titanium layer and a titanium nitride layer and gap-filling a tungsten layer. A planarization process and an etchback process are performed so that the trench 23 is partially filled. The titanium layer and the titanium nitride layer are a barrier metal. If necessary, after forming the barrier metal, a silicide may be formed on the surface of the junction region 50. The silicide serves as an ohmic contact between the junction region 50 and the buried bitline 51 and reduces a contact resistance.

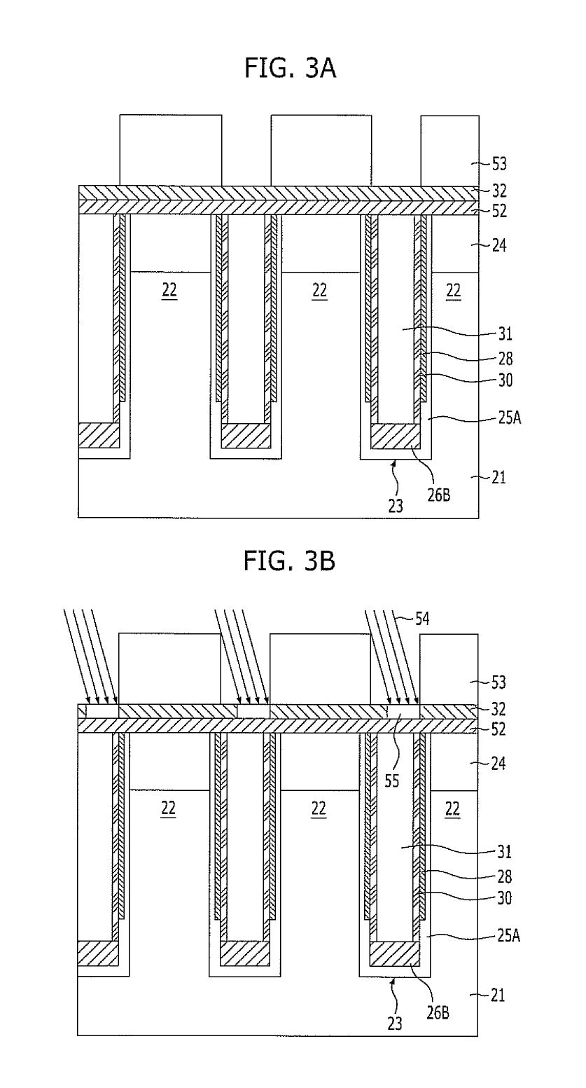

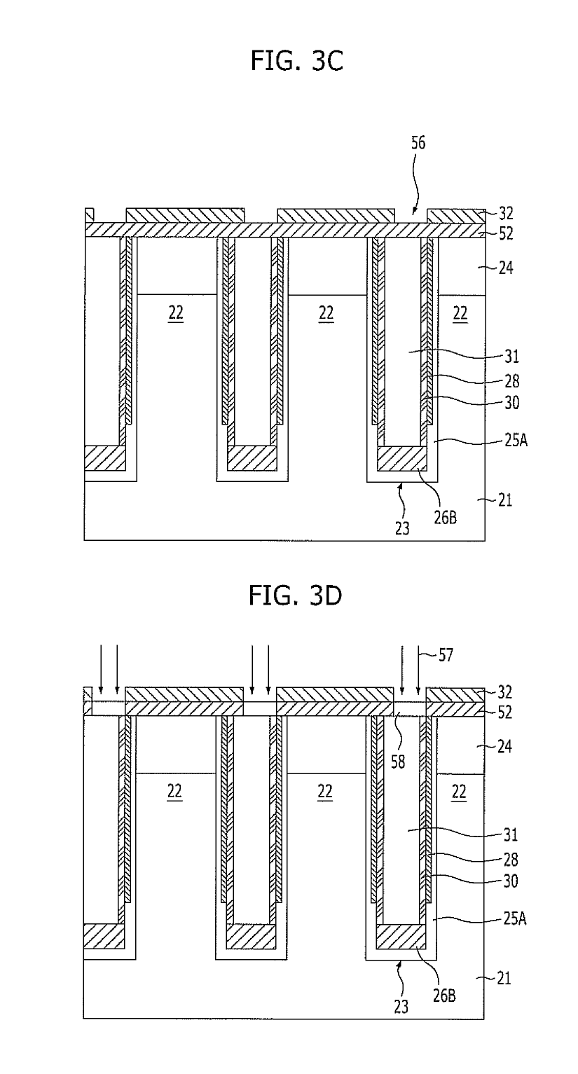

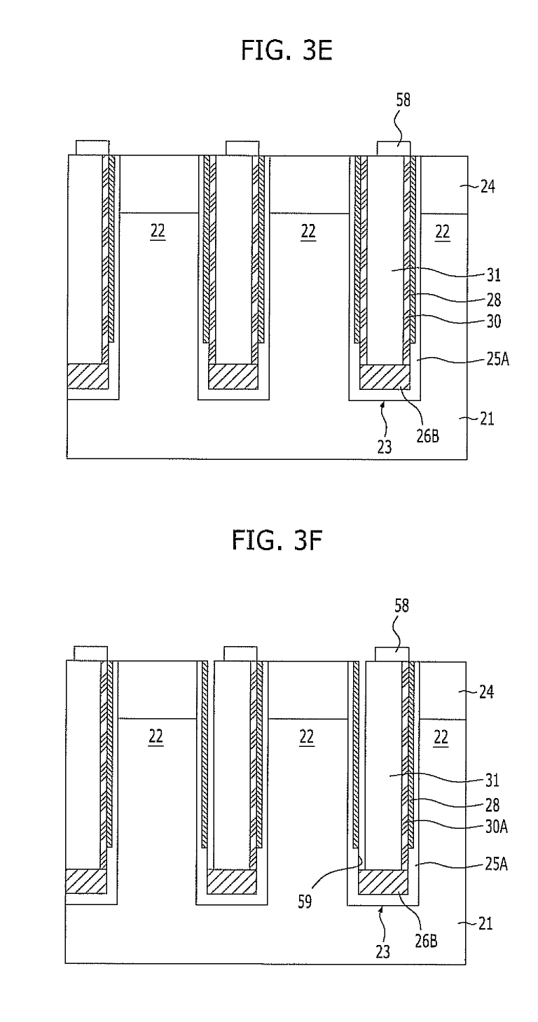

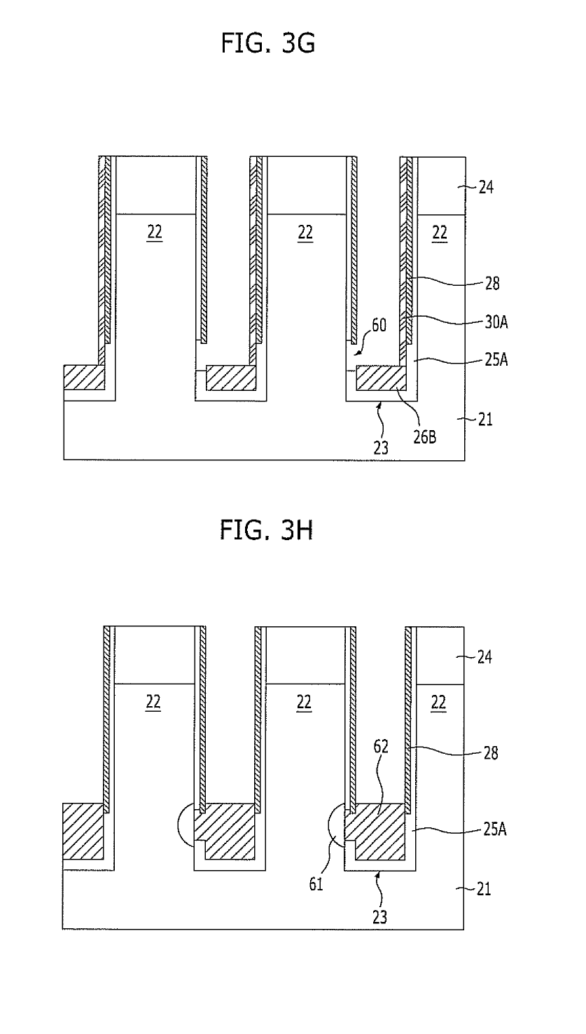

FIGS. 3A to 3H illustrate a method for forming a side contact of a semiconductor device in accordance with a third embodiment of the present invention.

Referring to FIG. 3A, a sacrificial spacer 30 and a planarized second sacrificial layer 31 are formed using the method of FIGS. 1A to 1D.

A passivation layer 52 is formed on a resulting structure including the planarized second sacrificial layer 31. The passivation layer 52 is formed using a polysilicon layer. The passivation layer 52 includes an undoped polysilicon layer. The passivation layer 52 prevents the second sacrificial layer 32 formed of oxide from being removed during a subsequent process of removing a damaged region.

A masking layer 32 is formed on the passivation layer 52. The masking layer 32 includes a silicon nitride layer.

A barrier pattern 53 is formed on the masking layer 32. The barrier pattern 53 has a vertical sidewall profile. The barrier pattern 53 may include a photoresist pattern. The barrier pattern 53 includes a positive photoresist layer.

Referring to FIG. 3B, a tilt ion implantation process 54 is performed using the barrier pattern 53 as an ion implantation barrier. At this time, the tilt ion implantation process 54 is performed at a desired tilt angle. Accordingly, a first damaged region 55 is formed in the masking layer 32.

The tilt ion implantation process 54 uses BF₂ as a dopant source. Accordingly, the first damaged region 55 is doped with boron. In a case in which the masking layer 32 includes a silicon nitride layer, the first damaged region 55 becomes a silicon boron nitride (SiBN) layer. The tilt ion implantation process 54 may be performed several times.

One end of the first damaged region 55 covers at least the top surface of the sacrificial spacer 30 on the passivation layer 52. Therefore, one of the sacrificial spacers 30 at each trench 23 is covered by the first damaged region 55, and the other spacer 30 is covered by the undoped masking layer 32.

Referring to FIG. 3C, the barrier pattern 53 is removed. In a case in which the barrier pattern 53 is a photoresist pattern, it is stripped using oxygen plasma.

The first damaged region 55 is selectively removed. The first damaged region 55 is a region of the mask layer 32 which is doped by the ion implantation. An etch rate is different depending on the absence and presence of doping. For example, in a case in which the masking layer 32 is a silicon nitride layer, the first damaged region 55 is a silicon boron nitride layer. According to an example, the etch rate is faster in the silicon boron nitride layer than in the silicon nitride layer. Therefore, the silicon boron nitride layer may be selectively removed using a BOE chemical. The undoped masking layer 32 is not removed because it has an etch selectivity to the BOE chemical. Although the BOE chemical is a solution for etching an oxide layer, it is also used to etch the silicon boron nitride layer. During the ion implantation process, the damaged region is formed, and the damaged region is easily etched by the HF or the BOE chemical. Therefore, the silicon boron nitride layer is easily etched by the BOE chemical. In the BOE chemical, the etch rate of the silicon nitride layer on which the tilt ion implantation process 54 of boron has been performed is about 425 times faster than that of the undoped silicon nitride layer. The etch rate is further increased as the number of times of the ion implantation process is performed increases. According to an example, when the tilt ion implantation process 54 is performed twice, the etch rate of the silicon nitride layer on which the tilt ion implantation process has been performed is about 631 times faster, as compared to the undoped silicon nitride layer.

As described above, when the first damaged region 55 is removed, an open region 56 is formed in the masking layer 32. The top surface of the passivation layer 52 is partially exposed by the open region 56.

Referring to FIG. 3D, an ion implantation process 57 is performed using the remaining masking layer 32 as an ion implantation barrier. At this time, the ion implantation process is performed in a vertical direction. Accordingly, a second damaged region 58 is formed in the passivation layer 52.

The ion implantation process 57 uses BF₂ as a dopant source. Accordingly, the second damaged region 58 is doped with boron. In a case in which the passivation layer 52 includes a polysilicon layer, the second damaged region 58 becomes a polysilicon layer doped with boron. The ion implantation process 57 may be performed several times.

One end of the second damaged region 58 covers at least the top surface of the sacrificial spacer 30. Therefore, one of the sacrificial spacers 30 at each trench 23 is covered by the second damaged region 58, and the other spacer 30 is covered by the undoped passivation layer 52.

Referring to FIG. 3E, the masking layer 32 is removed. Since the masking layer 32 is damaged during the ion implantation process, it is removed using a BOE chemical.

The remaining passivation layer 52 except for the second damaged region 58 is selectively removed. For example, in a case in which the passivation layer 52 is a polysilicon layer, the second damaged region 58 is a polysilicon layer doped with boron. In general, the etch rate of the undoped silicon layer is faster than the etch rate of the doped silicon layer. Therefore, the undoped polysilicon layer may be selectively removed using a mixed solution of a nitric acid and a hydrofluoric acid.

As described above, when the undoped region of the passivation layer 52 is removed, only the second damaged region 58 remains. One of the sacrificial spacers 30 in each trench 23 is exposed by the second damaged region 58.

Referring to FIG. 3F, the sacrificial spacer 30 exposed by the second damaged region 58 is removed. In a case in which the sacrificial spacer 30 includes a titanium nitride layer, an SPM cleaning is used. By removing the sacrificial layer 30, a portion of the first liner pattern 25A is exposed as indicated by reference numeral 59. The remaining sacrificial spacer is represented by reference numeral 30A.

Referring to FIG. 3G, the second damaged region 58 is removed. The second damaged region 58 may be removed by a wet etch process or a dry etch process.

A side contact 60 is formed by selectively removing the exposed first liner pattern 25A. Since the first liner pattern 25A is an oxide layer, a BOE chemical is used. When the BOE chemical is used in order to form the side contact 60, the second sacrificial layer 31 being an oxide layer is also removed at the same time.

The side contact 60 exposes a portion of a sidewall of the body 22. In forming the side contact 60, the first sacrificial pattern 26B, the sacrificial spacer 30A, and the second liner pattern 28 serve as an etch barrier.

Referring to FIG. 3H, the first sacrificial pattern 26B and the sacrificial spacer 30A are removed. Since the first sacrificial pattern 26B is a polysilicon layer, it is removed using a mixed chemical of a nitric acid and a hydrofluoric acid. The sacrificial spacer 30A is removed using an SPM solution.

A junction region 61 is formed at a sidewall of the body 22 exposed by the side contact 60. According to an example, the junction region 61 may be formed using an ion implantation process or a plasma doping process. According to another example, the junction region 61 may be formed by gap-filling a doped layer such as a doped polysilicon layer and performing a thermal treatment thereon. A dopant doped into the doped layer may include an N-type impurity such as phosphorus (P). Therefore, the junction region 50 becomes an N-type junction.

A buried bitline 62 which is connected to the junction region 61 and partially fills the trench 23 is formed. The buried bitline 62 includes a titanium (Ti) layer, a titanium nitride (TiN) layer, and a tungsten (W) layer. For example, the buried bitline 62 is formed by thinly forming a titanium layer and a titanium nitride layer and gap-filling a tungsten layer. A planarization process and an etchback process are performed so that the trench 23 is partially filled. The titanium layer and the titanium nitride layer are a barrier metal. If necessary, after forming the barrier metal, a silicide may be formed on the surface of the junction region 61. The silicide serves as an ohmic contact between the junction region 61 and the buried bitline 62 and reduces a contact resistance.

In accordance with the exemplary embodiments of the present invention, since the masking layer is formed by applying the ion implantation process using the sidewall profile of the barrier pattern, a side contact having a uniform depth and position may be formed.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, the method comprising:
forming a trench by etching a substrate using a hard mask layer as an etch barrier;
forming an insulation material which covers sidewalls of the trench;
forming a sacrificial material which fills the trench and is planarized to expose the surface of the hard mask layer;
forming a masking layer having a damaged region over the sacrificial material;
selectively removing the damaged region of the masking layer;
exposing a portion of the insulation material, which is formed at a sidewall of the trench, by etching a portion of the sacrificial material using the remaining masking layer as a barrier; and
forming a side contact by removing the exposed insulation material.

2. The method of claim 1, wherein the forming of the first layer having the damaged region comprises:
forming a masking layer over the sacrificial material;
forming a barrier pattern over the masking layer; and
forming the damaged region by performing an ion implantation process on the masking layer using the barrier pattern as an ion implantation barrier.

3. The method of claim 2, wherein the barrier pattern comprises a photoresist pattern.

4. The method of claim 2, wherein the barrier pattern comprises a photoresist pattern and has a sidewall profile so as to have a bigger opening to the masking layer at the bottom of the sidewall than at the top of the sidewall.

5. The method of claim 4, wherein, in the ion implantation process, an ion implantation that is vertical with respect to the masking layer and an ion implantation at a tilt angle with respect to the masking layer that is at the same angle as a tilt angle of the sidewall profile of the barrier pattern are sequentially performed.

6. The method of claim 4, wherein the photoresist pattern comprises a negative photoresist layer.

7. The method of claim 2, wherein the barrier pattern comprises a photoresist pattern having a vertical sidewall profile.

8. The method of claim 7, wherein the ion implantation process is performed by a tilt ion implantation at a tilt angle with respect to the masking layer.

9. The method of claim 1, wherein the masking layer comprises a silicon nitride layer.

10. The method of claim 9, wherein the damaged region comprises a silicon boron nitride layer into which boron ions are implanted.

11. The method of claim 1, wherein the forming of the sacrificial material comprises:
forming sacrificial spacers at sidewalls of the insulation material;
forming a sacrificial layer over the sacrificial spacers to gap-fill the trench; and
planarizing the sacrificial layer to expose the hard mask layer,
wherein, when one of the sacrificial spacers is removed, a portion of the insulation material formed at a sidewall of the trench is exposed.

12. The method of claim 11, wherein the sacrificial spacer comprises a titanium nitride layer, and the sacrificial layer comprises an oxide layer.

13. The method of claim 11, wherein the forming of the masking layer includes performing a first ion-implantation to form a first region of the damaged region and subsequently performing a second ion-implantation to form a second region of the damaged region.

14. The method of claim 13, wherein the first region of the damaged region does not cover the insulation material formed on the sidewall of the trench.

15. A method for fabricating a semiconductor device, the method comprising:
forming a trench by etching a substrate using a hard mask layer as an etch barrier;
forming an insulation material which covers sidewalls of the trench;
forming a sacrificial material which fills the trench and is planarized to expose the surface of the hard mask layer;
sequentially forming a passivation layer and a masking layer over the sacrificial material;
forming a first damaged region in the masking layer;
selectively removing the first damaged region;
forming a second damaged region in the passivation layer;
selectively removing the passivation layer so that the second damaged region remains;
exposing a portion of the insulation material, which is formed at a sidewall of the trench, by etching a portion of the sacrificial material using the second damaged region as a barrier; and
forming a side contact by removing the exposed insulation material.

16. The method of claim 15, wherein the forming of the first damaged region comprises:
forming a barrier pattern over the masking layer; and
forming the first damaged region by performing a primary ion implantation process on the masking layer using the barrier pattern as an ion implantation barrier.

17. The method of claim 16, wherein the primary ion implantation process is performed by a tilt ion implantation at a tilt angle with respect to the masking layer.

18. The method of claim 15, wherein the forming of the second damaged region in the passivation layer comprises a performing ion implantation at a vertical angle with respect to the passivation layer.

19. The method of claim 15, wherein the masking layer comprises a silicon nitride layer and the passivation layer comprises a polysilicon layer.

20. The method of claim 15, wherein the forming of the sacrificial material comprises:
forming sacrificial spacers at sidewalls of the insulation material;
forming a sacrificial layer over the sacrificial spacers to gap-fill the trench; and
planarizing the sacrificial layer to expose the hard mask layer,
wherein, when one of the sacrificial spacers is removed, a portion of the insulation material formed at a sidewall of the trench is exposed.
